(19) United States
(12) Patent Application Publication
(10) Pub. No.: US 2008/0171424 A1
(43) Pub. Date: Jul. 17, 2008

(54) Epitaxial growth of GaN and SiC on silicon using nanowires and nanosize nucleus methodologies

(75) Inventors: Tingkai Li, Vancouver, WA (US); Jer-Shen Maa, Vancouver, WA (US); Douglas J. Tweet, Camas, WA (US); Wei-Wei Zhuang, Vancouver, WA (US); Sheng Teng Hsu, Camas, WA (US)

Correspondence Address: David C. Ripma;Sharp Laboratories of America, Inc., 5750 NW Pacific Rim Boulevard, Camas, WA, 97202, US

(73) Assignee: Sharp Laboratories of America, Inc.

(21) Appl. No.: 11/653,802

(22) Filed: Jan. 16, 2007

(51) Int. Cl. H01L 21/205

(52) U.S. Cl. 438/496; 257/E21.101; 977/721

(57) ABSTRACT

A method of fabricating a continuous layer of a defect sensitive material on a silicon substrate includes preparing a silicon substrate; forming a nanostructure array directly on the silicon substrate; depositing a selective growth enhancing layer on the substrate; smoothing the selective growth enhancing layer; and growing a continuous layer of the defect sensitive material on the nanostructure array.

### FIELD OF THE INVENTION

This invention relates to formation of GaN and SiC films on silicon substrates for use in power devices.

### BACKGROUND OF THE INVENTION

Silicon substrates are low cost, available in large diameters and have well characterized electrical and thermal properties. Despite these advantages silicon has not been popular as a substrate material for GaN and SiC, and other compound semiconductors growth because of silicon's shortcomings when combined with defect sensitive materials, such as GaN and SiC, such as defects and cracking of the GaN or SiC film due to stress. Consequently, until recently, the properties of GaN and SiC on silicon were rather poor.

The problems associated with silicon are as follows: The lattice mismatch between silicon, GaN and SiC is almost 16% and 20%, respectively, which cause a high dislocation density in the GaN and SiC layers. A more significant problem is the thermal mismatch, which is 54% and 17% for GaN and SiC, respectively, on silicon. Therefore, it is not possible, using known techniques, to form thick epilayers of GaN or SiC without cracks and having a low defect density. In order to solve these problems, a seed layer, or buffer layer, such as AlN, InGaN, AlGaN, has been used to accommodate the lattice and thermal mismatch between the substrate and the epilayer. Other methods have also been used, including doped layers, patterned substrates, porous silicon, and superlattice structures. Nevertheless, formation of high quality epitaxial GaN and SiC films on silicon are still not available by conventional techniques.

Techniques for growing GaN on silicon substrates are listed in the following table, followed by identification of the references:

| | | | Pressure | | |
|---|---|---|---|---|---|
| Process | Substrate | Temp. | (torr) | Buffer Layer | Reference |
| MOCVD | Si(111) | 1070° C. | 100 | AlN & SiNₓ | Kang et al. |
| MBE | Si(111) | 1250° C. | | SiNₓ | Wang et al. |
| MOCVD | Si(111) | 1050° C.–1100° C. | 500 | AlN | Jamil et al. |
| MOCVD | Si(111) | 1050° C. | | AlN | Raghaven et al. (I) |
| MOCVD | Si(111) | 1010° C. | 200 | AlN (100 nm) | Zang et al. |
| MOCVD | Si(111) | 1020° C.–1050° C. | 50–250 | AlN/InGaN | Mastro et al. |
| Rf- | Si(100) and | | | AlN Only | Ligatchev et al. |
| Sputtering | 4H—SiC | | | | |
| MOCVD | Si(111) | 1030° C. | | AlN (750° C.) | Chen et al.(I) |
| MOCVD | Si(111) | 1050° C. | 76 | AlN (1080° C.) | Lu et al. |
| MOCVD | Si(111) | 1100° C. | 100 | AlN | Raghavan et al. (II) |
| | | | | | and (III) |
| MOCVD | Si(111) | 845° C.–1150° C. | 100 mb | AlN | Chen et al. (II) |
| MOVPE | Si(111) | 1145° C. | | AlN/InGaN | Schulze et al. |

Kang et al., Reduction of dislocations in GaN epilayers grown on Si(111) substrate using Si_{X}N_{Y} inserting layer, Appl. Phys. Lett. Vol. 85, No. 9, pp1502–1504 (2004) describe growth of a GaN layer on a silicon substrate with plural buffer layers between the silicon substrate and the GaN overlying layer.

Wang et al., Atomistic study of GaN surface grown on Si(111), Appl. Phys. Lett. 87, 032110-1-032110-3 (2005), describes RF MBE of GaN on silicon (111).

Jamil et al., Development of strain reduced GaN on Si (111) by substrate engineering, Appl. Phys. Lett. 87, 082103-1-082103-3 (2005) describe growth of a GaN layer on a AlN/Si substrate.

Macht et al., Microphotoluminescence mapping of laterally overgrown GaN layers on patterned Si (111) substrates, Appl. Phys. Lett. 87, 131904-1-131904-3 (2005) describe growth of a non-continuous, non-uniform GaN layer on a silicon substrate having holes etched therein.

Raghavan et al. (I), Effect of AlN interlayers on growth stress in GaN layers deposited on (111) Si, Appl. Phys. Lett. 87, 142101-1-142101-3 (2005) describe a stress-reduced GaN layer grown on a AlN buffer layer.

Zang et al., Nanoscale lateral epitaxial overgrowth on GaN on Si (111), Appl. Phys. Lett. 87, 193106-193106-3 (2005) describe MOCVD of GaN on a substrate of silicon having an AlN buffer layer thereon, and nanoholes formed in an SiO₂ mask.

Mastro et al., High-reflectance III-nitride distributed Bragg reflectors grown on Si Substrates, Appl. Phys. Left. 87, 241103-1-241103-3 (2005) describes formation of a AlGaN layer on a silicon substrate having an AlN buffer layer thereon.

Ligatchev et al., Density of defect states of aluminum nitride grown on silicon and silicon carbide substrates at room temperature, Appl. Phys. Lett. 87, 242903-242903-3 (2005) describe fabrication of a AlN film on a silicon substrate having a 4H—SiC buffer layer thereon.

Chen et al. (I), Growth and characteristics of low dislocation density GaN grown on Si (111) from a single process, Appl. Phys. Lett. 88, 031916-1-031916-3 (2006) describe technique for reducing defect density in a GaN film.

Lu et al., Growth of crack-free GaN films on Si (111) substrate by using Al-rich AlN buffer layer, Jour. Appl. Phys. Vol. 96, No. 9, pp 4982-4988 (2004) describe technique for reducing cracks in a GaN film.

Raghavan et al. (II), Growth stresses and cracking in GaN films on (111) Si grown by metal-organic chemical-vapor deposition. I. AlN buffer layers, Jour. Appl. Phys. 98, 023514-1-023514-9 (2005), and Raghavan et al. (III), Growth stresses and cracking in GaN films on (111) Si grown by metalorganic chemical vapor deposition. II. Graded AlGaN buffer layers, Jour. Appl. Phys. 98, 023515-1-023515-8 (2005) describe a stress-reduced and reduced cracking GaN layer grown on a AlN buffer layer.

Chen et al. (II), Stress relaxation in the GaN/AlN multilayers grown on a mesh-patterned Si (111) substrate, Jour. Appl. Phys. 98, 093509-1-093509-5 (2005) describe stress reduction through use of an AlN layer.

Schulze et al., Growth of GaN-based devices on Si (001) by MOVPE, Poster, F F 27.1 MRSFall-2005 depict various features of GaN-based devices.

Kleimann et al., Toward the formation of three-dimensional nanostructures by electrochemical etching of silicon, Appl. Phys. Lett. 86, 183108-1-183108-3 (2005) describe lithographic etching techniques.

Schubert et al., Silicon nanowhiskers grown on (111) Si substrates by molecular-beam epitaxy, Appl. Phys. Lett. Vol. 84, No. 24, pp 4968-4970 (2004) describe use of gold seeds to grow silicon nanowhiskers.

### SUMMARY OF THE INVENTION

A method of fabricating a continuous layer of a defect sensitive material on a silicon substrate includes preparing a silicon substrate; forming a nanostructure array directly on the silicon substrate; depositing a selective growth enhancing layer on the substrate; smoothing the selective growth enhancing layer; and growing a continuous layer of the defect sensitive material on the nanostructure array.

It is an object of the invention to provide a continuous, thick film layer of an otherwise defect-sensitive material on a silicon substrate.

Another object of the invention is to provide a method of fabricating a continuous, relatively defect-free layer of GaN or SiC on a silicon substrate.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram depicting the steps of the method of the invention.

FIGS. 2-8 depicts various embodiments of structures fabricated according to the method of the invention.

### DETAILED DESCRIPTION OF THE PREFERRED EMBODIMENTS

This invention provides a solution that significantly reduces the thermal and lattice mismatch problem using lateral epitaxial overgrowth of GaN on silicon, and nanowire technologies.

Patterning substrates, by masking or etching, or provision of a buffer layer are highly effective ways to reduce stress or cracks. In the method of the invention, a Si₃N₄ or SiO₂ layer, referred to herein as a selective growth enhancing layer, is deposited over the silicon substrate in a patterned manner, or with deep trenches formed in the masked materials. Ultimately, lateral epitaxial overgrowth (LEO) of GaN is performed. Defects may be reduced and a relatively thick layer, having a thickness in the range of 1 μm to 3 μm of GaN film formed on a patterned silicon area, which patterned area is not a continuous film. It also has been demonstrated, both theoretically and experimentally, that stress relief is provided by a nanosize nucleus. The 3-D strain in a nanosize nucleus provides exponential stress/strain decay, with the decay length proportional to, and of similar magnitude to, island diameter, therefore, the strain energy saturates at a maximum value. Thick high quality epi-GaN and SiC may be deposited on silicon using nanosize nucleus technologies. Using a nanostructure array on silicon, with or without an insulator (SOI) substrate, nanosize island arrays are created, while a SiO₂ or SiₓN_{y} layer provides selectivity during MOCVD growth. MOCVD selective growth is performed to grow GaN or SiC on silicon nanowires. Then, lateral epitaxial overgrowth (LEO) is performed to allow coalescence of continuous, crack-free, high-quality GaN and SiC thick films. The space between the nanostructures facilitates release of thermal stress in the thick GaN or SiC layer.

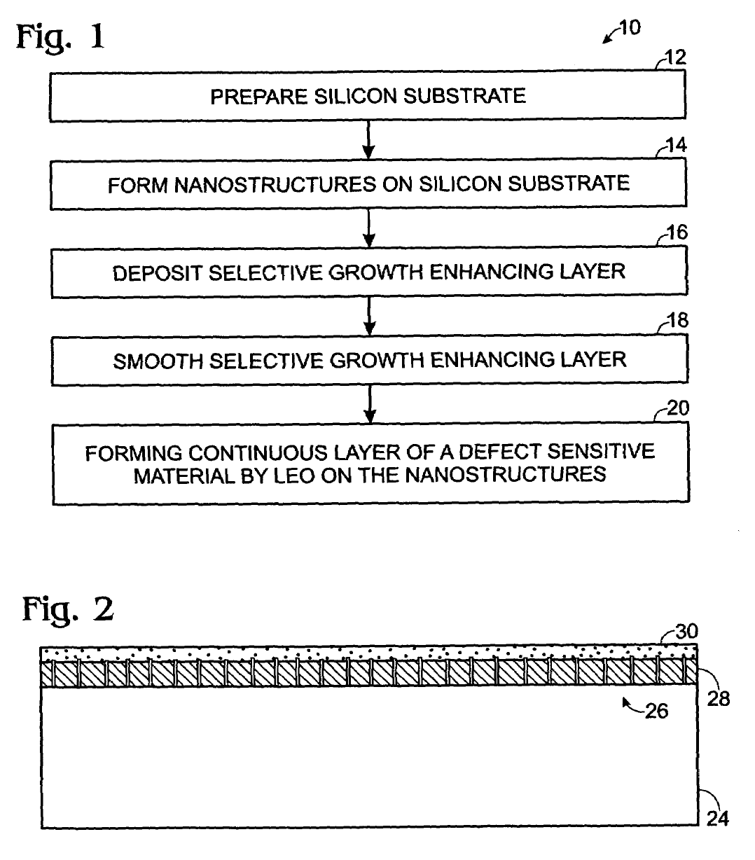

Referring now to FIG. 1, the method of the invention is depicted generally at 10, and includes preparation of a silicon substrate 12, which may be a silicon or SOI substrate. The method of the invention next requires that nanostructures, such as nanowire, nanoholes, nanotubes or nanoparticles, be fabricated directly on the silicon substrate, 14, to create nanosize growth island arrays. A layer of SiO₂ or SiₓN_{y}, referred to herein as a selective growth enhancing layer, is deposited, 16, and provides selectivity during a subsequent deposition step. The selective growth enhancing layer is smoothed, 18. Selective deposition 20, usually by MOCVD, of a layer of a defect sensitive material, such as GaN or SiC, on the nanostructures is the next step. Lateral epitaxial overgrowth (LEO), which may be combined with a buffer layer, is performed to provide coalescence of crack-free, high quality GaN and SiC thick films. The space between the nanostructures facilitates in the release of thermal stress in a thick GaN or SiC layer.

The following processes are for epi-GaN and SiC grown on silicon substrates. The fabrication processes for specific embodiments of structures fabricated according to the method of the invention are as follows:

### Embodiment 1: GaN or SiC Growth on Silicon Using Silicon Nanowires

Referring to FIG. 2, a silicon (111) substrate 24 is prepared. A silicon nanowire array 26 is formed by etching or patterning and CVD. The nanowires in array 24 have a diameter of between about 50 nm and 500 nm, and a height of between about 0.5 μm and 3 μm. A layer of SiO₂ or SiₓN_{y}, 28, is deposited to a thickness of between about 1.0 μm and 5 μm, and smoothed, as by CMP, stopping at top of silicon nanowire array 26. The structure is cleaned by in an HF dip to expose tops of the silicon nanowires in the array. A layer of GaN or SiC 30 is formed on the silicon nanowire array by selective LEO, to a thickness of between about 1 μm and 3 μm.

### Embodiment 2: GaN or SiC Growth on Silicon Using Silicon Nanowires with Cavities Between Nanowires

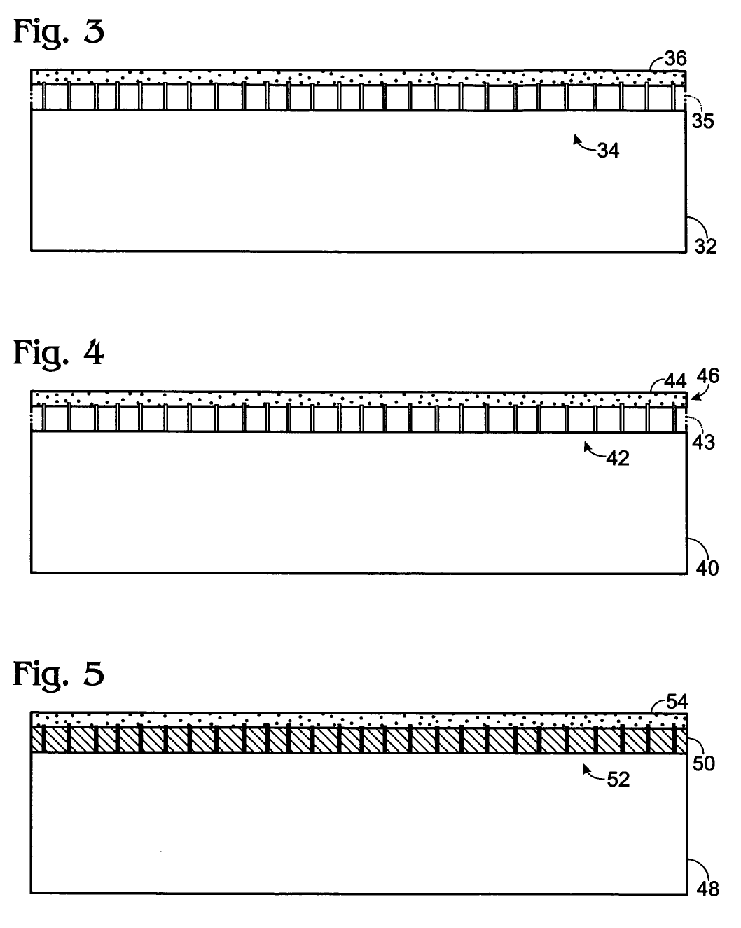

Referring to FIG. 3, a silicon (111) substrate 32 is prepared. A silicon nanowire array 34 is fabricated by etching or CVD methods. A layer of SiO₂ or SiₓN_{y} 35 is deposited and smoothed by CMP, stopping at top of the silicon nanowire array. Layer 35 is shown in phantom in the figure, as the layer is removed prior to the stage of the method of the invention depicted in the figure. Cleaning is accomplished by a HF dip to expose the tops of the silicon nanowires in the array. Selective LEO of a GaN or SiC layer 36 is performed to form islands of GaN or SiC on the silicon nanowires, which LEO is stopped before the GaN or SiC layer coalesces. The remaining SiO₂ or SiₓN_{y}, is etched to remove the layer, and the LEO continued. This results in a porous layer 38 underneath a continuous GaN or SiC film.

### Embodiment 3: GaN or SiC Growth on Silicon Using Silicon Nanowires with Spacer Oxide

Referring to FIG. 4, a silicon (111) substrate 40 is prepared. A silicon nanowire array 42 is fabricated by etching or CVD methods. A layer of SiO₂, SiₓN_{y} 43 is deposited directly on nanostructure array 42, followed by spacer etching of the SiO₂ or SiₓN_{y}. Again, layer 43 is depicted in phantom. Cleaning by an HF dip exposes the tops of the silicon nanowires in array 42. Selective LEO of a GaN or SiC layer 44 on the silicon nanowires is performed, stopping before the GaN or SiC layer coalesces. The remaining SiO₂ or SiₓN_{y}, is etched, and LEO continues. This also results in a porous layer 46 underneath a continuous GaN or SiC film.

### Embodiment 4: GaN or SiC Growth on Silicon Using SiO₂ Nanoholes

Referring to FIG. 5, a silicon (111) substrate 48 is prepared. A layer of SiO₂ or SiₓN_{y} 50 is deposited directly on substrate 48. A silicon nanohole array 52 is fabricated in layer 50 using an etching process, stopping at the level of the silicon substrate. An HF dip is used to expose the surface of the silicon substrate. LEO GaN or SiC 54 on silicon nanoholes provides a continuous layer of GaN or SiC.

### Embodiment 5: GaN or SiC Growth on Silicon Using Silicon Nanoholes

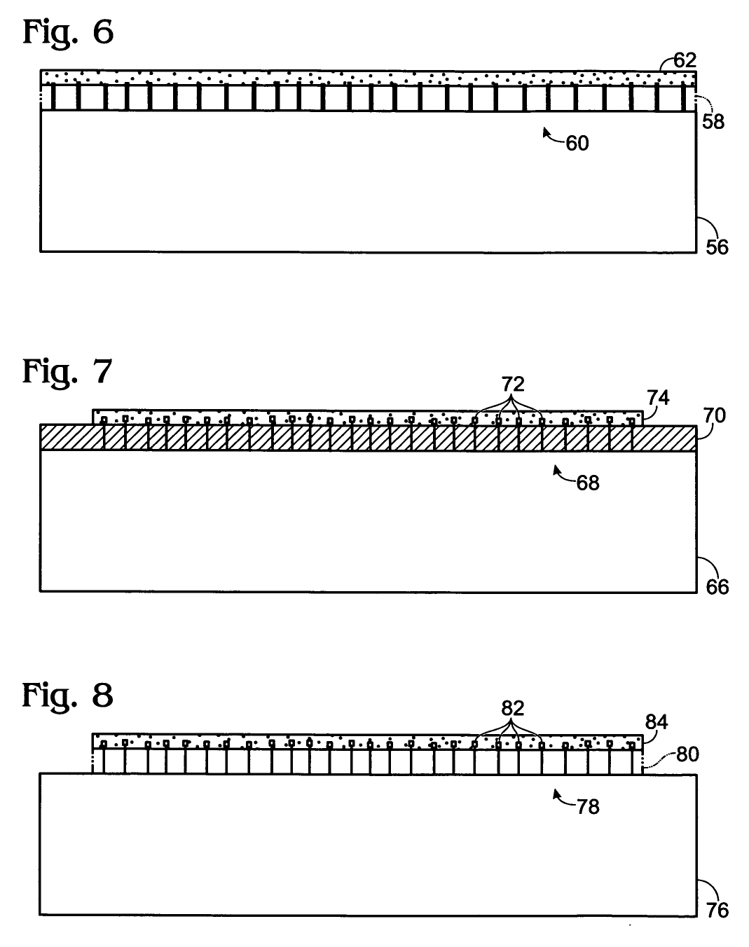

Referring to FIG. 6, a silicon (111) substrate 56 is prepared. A layer of SiO₂ or SiₓN_{y} 58 is deposited (shown in phantom), is pattered, and an array 60 of nanoholes is formed by etching, stopping at the silicon substrate surface. An HF dip exposes the surface of the silicon substrate. Selective LEO of GaN or SiC 62 on silicon provides an array of GaN or SiC islands, with the LEO being terminated layer of GaN or SiC coalesces. The remaining SiO₂ or SiₓN_{y}, is completely removed by etching, and the LEO resumed to provide a continuous layer of GaN or SiC. This also results in a porous layer 64 underneath a continuous GaN or SiC film.

### Embodiment 6: GaN Growth on Silicon Using Silicon Nanowires with SiC

Referring to FIG. 7, a silicon (111) substrate 66 is prepared. A silicon nanowire array 68 is formed by etching or CVD. A layer of SiO₂ or SiₓN_{y} 70 is deposited and smoothed by CMP, stopping at top of the silicon nanowire array. An HF dip exposes the tops of the silicon nanowires. Selective deposition of SiC islands 72 on the silicon nanowires is stopped before the SiC layer coalesces. Selective LEO of GaN on the SiC islands and silicon nanowires results in a continuous layer of GaN.

### Embodiment 7: GaN Growth on Silicon Using Silicon Nanowires with SiC

Referring to FIG. 8, a silicon (111) substrate 76 is prepared. A silicon nanowire array 78 is formed by etching or CVD. A layer of SiO₂ or SiₓN_{y} 80 (shown in phantom) is deposited and smoothed by CMP, stopping at top of the silicon nanowires in the array. An HF dip exposes the tops of the silicon nanowires. Selective deposition of SiC islands 82 on the silicon nanowires is performed, and terminated before the SiC layer coalesces. The remaining SiO₂ or SiₓN_{y} is completely removed by etching. Selective LEO of a continuous layer of GaN 84 is preformed on the silicon nanowires and the SiC island.

Thus, a method for fabricating a relatively thick continuous layer of GaN or SiC on a silicon substrate has been disclosed. It will be appreciated that further variations and modifications thereof may be made within the scope of the invention as defined in the appended claims.

We claim:

1. A method of fabricating a continuous layer of a defect sensitive material on a silicon substrate, comprising:
preparing a silicon substrate;
forming a nanostructure array directly on the silicon substrate;
depositing a selective growth enhancing layer on the substrate;
smoothing the selective growth enhancing layer; and
growing a continuous layer of the defect sensitive material on the nanostructure array.

2. The method of claim 1 wherein said silicon substrate is a SOI substrate.

3. The method of claim 1 wherein said growth enhancing layer is taken from the group of materials consisting of SiO₂ and SiₓN_{y}.

4. The method of claim 1 wherein said nanostructures include nanotubes, nanowires, nanoholes and nanoparticles.

5. The method of claim 1 wherein said nanostructures are formed by a formation process taken from the group of processes consisting of etching and patterning and CVD.

6. The method of claim 1 wherein said smoothing the selective growth enhancing layer includes smoothing the selective growth enhancing layer by CMP.

7. The method of claim 1 wherein said growing a layer of a defect sensitive material on the nanostructure array includes depositing a layer of a defect sensitive material on the nanostructure array by MOCVD.

8. The method of claim 1 wherein said growing a layer of a defect sensitive material on the nanostructure array includes growing a layer of a defect sensitive material on the nanostructure array taken from the group of defect sensitive materials consisting of GaN and SiC.

9. The method of claim 1 wherein said growing a continuous layer includes LEO of a the defect sensitive material, stopping such LEO before the layer of defect sensitive material coalesces; etching the enhancing layer; and further growing of a layer of the defect sensitive material.

10. The method of claim 1 wherein, after said smoothing, selectively depositing SiC islands on the nanostructure array; wherein said selectively depositing SiC islands is stopped before coalescence of SiC island material.

11. A method of fabricating a continuous layer of a defect sensitive material on a silicon substrate, comprising:
preparing a silicon substrate;
forming a nanostructure array directly on the silicon substrate;
depositing a selective growth enhancing layer on the substrate, taken from the group of materials consisting of SiO₂ and SiₓN_{y};
smoothing the selective growth enhancing layer; and
growing a continuous layer of a material by LEO taken from the group of materials consisting of GaN and SiC on the nanostructure array by MOCVD.

12. The method of claim 11 wherein said silicon substrate is a SOI substrate.

13. The method of claim 11 wherein said nanostructures include nanotubes, nanowires, nanoholes and nanoparticles.

14. The method of claim 11 wherein said nanostructures are formed by a formation process taken from the group of processes consisting of etching and patterning and CVD.

15. The method of claim 11 wherein said smoothing the selective growth enhancing layer includes smoothing the selective growth enhancing layer by CMP.

16. The method of claim 11 wherein said growing a continuous layer includes stopping such LEO before the layer of material coalesces; etching the enhancing layer; and further growing of a layer of the material.

17. The method of claim 11 wherein, after said smoothing, selectively depositing SiC islands on the nanostructure array; wherein said selectively depositing SiC islands is stopped before coalescense of SiC island material.
